(19) United States
(12) Patent Application Publication
(10) Pub. No.: US 2003/0047760 A1
(43) Pub. Date: Mar. 13, 2003

(54) Electronic component with at least two semiconductor chips, and process for its production

(76) Inventors: Frank Daeche, Munchen (DE); Bernhard Zuhr, Regensburg (DE)

Correspondence Address: LERNER AND GREENBERG, P.A., Post Office Box 2480, Hollywood, FL, 33022-2480, US

(21) Appl. No.: 10/232,171

(22) Filed: Aug. 30, 2002

(30) Foreign Application Priority Data
Aug. 30, 2001 (DE) 101 42 114.1

(51) Int. Cl. H01L 29/80

(52) U.S. Cl. 257/257

(57) ABSTRACT

An electronic component includes two semiconductor chips on an intermediate carrier, which is provided on its underside with external contacts, which are located on a plane with first external contacts on a first active chip surface of the first semiconductor chip. A rear side of the first semiconductor chip faces an active chip surface of the second semiconductor chip. The invention additionally relates to a process for the production of the electronic component.

### BACKGROUND OF THE INVENTION

### FIELD OF THE INVENTION

The invention relates to an electronic component with at least two semiconductor chips and to a process for its production.

In many electronic components, a first semiconductor chip module, for example, a processor module, and a second semiconductor module, for example, a memory module, are needed. To save space on a printed circuit board, it is expedient to accommodate both semiconductor chip modules in a common housing with the smallest possible space requirement. Now, a processor module typically has a square base area and a memory module has a rectangular base area so that in the case of semiconductor chip modules that are dispose one above the other, such as in a prior art chip-on-chip construction, the bonding contact areas, to some extent, cover one another.

Such a problem can be solved by the two semiconductor chip modules being disposed beside each other in a common housing, which gives rise to a considerable space requirement. In an alternative solution, the two semiconductor chip modules are mounted in a leadframe housing, which entails complicated assembly, because the components have to be turned many times and, in the process, the bonding wires to some extent are exposed. A further principle is also applied, in which the semiconductor chip modules are mounted in different housings, which are then disposed one above the other. However, such a configuration is also a complicated and costly process that, in addition, leads to a high overall height of such an electronic component.

Japanese Patent document 08250651 A discloses a semiconductor configuration in which two semiconductor chip modules are disposed one above the other in spaces divided by an intermediate wall. The two semiconductor chip modules are connected to external contacts through conductor tracks by bonding wires. Such a prior art semiconductor configuration takes up a great deal of installation volume and is cumbersome and complicated to produce.

### SUMMARY OF THE INVENTION

It is accordingly an object of the invention to provide an electronic component with at least two semiconductor chips, and process for its production that overcomes the hereinafore-mentioned disadvantages of the heretofore-known devices and methods of this general type and that, to overcome the disadvantages of the prior art, can be constructed simply and produced economically and takes up a low volume.

With the foregoing and other objects in view, there is provided, in accordance with the invention, an electronic component, including at least one first semiconductor chip having a first active chip surface with first external contacts disposed in a given plane and a first passive rear side, at least one second semiconductor chip having a second active chip surface and a second passive rear side, the first passive rear side facing one of the second active chip surface and the second passive rear side, and an intermediate carrier having a carrier upper side holding the at least one second semiconductor chip and an underside having second external contacts located on the given plane.

According to the invention, the electronic component has at least one first semiconductor chip and at least one second semiconductor chip and an intermediate carrier to hold the semiconductor chips. Provision is made for the second semiconductor chip or chips to be fitted to an upper side of the intermediate carrier. On its underside, the intermediate carrier is provided with external contacts, which are located on a plane with first external contacts on a first active chip surface of the at least one first semiconductor chip so that the electronic component can be mounted on a printed circuit board. Provision is also made for a first passive rear side of the first semiconductor chip or chips to face a second passive rear side of the second semiconductor chip or chips.

The electronic component according to the invention has the advantage that, on account of the semiconductor chips being joined to one another, two semiconductor chip modules with different external dimensions can be accommodated in a common housing in an extremely space-saving manner. It is, thus, possible to stack a rectangular semiconductor chip with a square semiconductor chip and vice-versa, the semiconductor chips overlapping only to some extent and both semiconductor chips respectively having areas that project beyond the overlap. For external dimensions that are different in this way, the prior art does not provide any usable solution.

In accordance with another feature of the invention, the first external contacts on the first active chip surface of the at least one first semiconductor chip and the second external contacts on the underside of the intermediate carrier in each case to be formed as first and second contact bumps. Such an embodiment permits the mounting of the electronic component according to the invention in the flip-chip technique, which permits fast and cost-effective further processing of the electronic component, because it can be placed in a simple way on a printed circuit board and soldered thereto.

In accordance with a further feature of the invention, the at least one first semiconductor chip rests with its first passive rear side on the underside of the intermediate carrier and is permanently connected to the latter, which produces a very flat and compact electronic component. In another embodiment, the at least one first semiconductor chip rests with its first passive rear side on a second passive rear side of the second semiconductor chip and is permanently connected to the latter.

Such an alternative embodiment has, in particular, the advantage of an extremely compact configuration because the two semiconductor chips in this case are not separated by a layer of the intermediate carrier but are joined directly to each other. In such an embodiment, both the upper side and the underside of the intermediate carrier are in each case contoured to be flat, the intermediate carrier including a frame and a central cutout. The first semiconductor chip can, thus, be disposed in the cutout and be at a short distance from the frame. The second semiconductor chip in this case functions as a carrier for the first semiconductor chip and is, itself, fixed to the frame of the intermediate carrier.

In accordance with an added feature of the invention, the at least one second semiconductor chip has its second passive rear side facing the first semiconductor chip and is electrically conductively connected to the upper side of the intermediate carrier by bonding wires. Such an embodiment has the advantage of a very compact configuration that, in addition, can be produced simply.

In accordance with an additional feature of the invention, the intermediate carrier has a stepped cross-section.

In accordance with yet another feature of the invention, the at least one second semiconductor chip has its second active chip surface facing the first semiconductor chip and to be electrically conductively connected to the upper side of the intermediate carrier by third external contacts, in the flip-chip technique. In such a case, there are electrical connections between the third external contacts of the second semiconductor chip and contact connecting areas on the upper side of the intermediate carrier.

The advantage lies in the extremely compact construction of the electronic component because a large number of third contact areas can be accommodated on the second active chip surface of the second semiconductor chip. The configuration leads to extremely compact dimensions of the electronic component.

In accordance with yet a further feature of the invention, the intermediate carrier is configured as a rerouting board. If appropriate, a three-dimensional rerouting structure can also be contained in the intermediate carrier, which leads to very compact dimensions of the electronic component according to the invention.

In accordance with yet an added feature of the invention, the at least one first semiconductor chip is square and is a processor module; and the at least one second semiconductor chip is rectangular and is a memory module.

The advantage of an electronic component constructed and produced in accordance with the invention is that a memory module having a rectangular form and a processor module having a square form can be electrically connected to each other reliably in an extremely small space. It is also possible for a plurality of memory modules to be combined with a processor module in an electronic component without difficulty. Alternatively, a plurality of processor modules can also be combined with one or more memory modules in an electronic component.

A housing that covers the intermediate carrier and closes the semiconductor chip can be configured as extremely flat and, therefore, very compact.

With the objects of the invention in view, there is also provided a method of producing an electronic component, including the steps of providing at least one first semiconductor chip having a first active chip surface having first contact areas and first external contacts, the first external contacts disposed in a given plane and a first passive rear side, at least one second semiconductor chip having a second active chip surface having second and third contact areas, a second passive rear side, and one of the second active chip surface and the second passive rear side facing the first passive rear side, and an intermediate carrier having a stepped cross-section, an upper side having contact connecting areas, and an underside having second external contacts disposed in the given plane, fixing the at least one second semiconductor chip to the upper side of the intermediate carrier, producing electrical connections between the second and third contact areas and the contact connecting areas, fixing the first passive rear side of the at least one first semiconductor chip to the underside of the intermediate carrier, and potting the at least one first semiconductor chip, the at least one second semiconductor chip, and the intermediate carrier in a housing.

A process according to the invention for the production of an electronic component according to one of the embodiments described previously has, in a first embodiment, steps described in the following text.

A first semiconductor chip with first contact areas on a first active chip surface is provided. A second semiconductor chip with second and third contact areas on a second active chip surface is provided. Also provided is an intermediate carrier with second external contacts on its underside and with contact connecting areas on its upper side, the carrier having a stepped cross-section.

The second semiconductor chip is fixed to the upper side of the intermediate carrier, for example, by an adhesive or solder layer. Between second and third contact areas of the second semiconductor chip and contact connecting areas on the upper side of the intermediate carrier, electrical connections are produced, after which the first semiconductor chip is fixed with its first passive rear side on the underside of the intermediate carrier, for example, by an adhesive or solder layer. The electronic component is finally potted in a housing. It is alternatively possible for only the upper side of the intermediate carrier with the second semiconductor chip and the electrical connections to be potted.

Such a process for the production of the electronic component according to the invention has the advantage of having very short production times and leads to very compact components.

In accordance with yet an additional mode of the invention, electrical connections are produced between second contact areas of the second semiconductor chip and contact connecting areas on the upper side of the intermediate carrier by bonding wires, which have the advantage of simple and cost-effective processability with very short process cycles.

In accordance with again another mode of the invention, electrical connections are produced between third contact areas of the second semiconductor chip and contact connecting areas on the upper side of the intermediate carrier by third external contacts. The third external contacts, preferably, include third contact bumps, which permit flip-chip mounting of the second semiconductor chip on the upper side of the intermediate carrier. Such a process permits a still more compact construction of the electronic component and also permits, in particular, mounting a plurality of second semiconductor chips on one intermediate carrier, which can optionally be connected to one or more first semiconductor chips.

With the objects of the invention in view, there is also provided a method of producing an electronic component, including the steps of providing at least one first semiconductor chip having a first active chip surface having first contact areas and first external contacts, the first external contacts disposed in a given plane and a first passive rear side, at least one second semiconductor chip having a second active chip surface having second contact areas and a second passive rear side facing the first passive rear side, and a flat intermediate carrier having a frame defining a central cutout, the frame having an upper side having an edge and contact connecting areas, supporting areas on the edge of the upper side of the frame, and an underside having second external contacts disposed in the given plane, holding at least one of the at least one first semiconductor chip and the at least one second semiconductor chip on the upper side of the intermediate carrier, joining the first passive rear side to the second passive rear side, fixing the at least one second semiconductor chip to the supporting areas, connecting the second contact areas to the contact connecting areas with bonding wires, and potting the at least one first semiconductor chip, the at least one second semiconductor chip, and the intermediate carrier in a housing.

The first and the second semiconductor chip are in each case joined with their passive rear sides on each other. The second semiconductor chip is placed on second supporting areas on the edge of the upper side of the frame of the intermediate carrier and connected thereto. Second contact areas of the second semiconductor chip are, then, connected to contact connecting areas of the intermediate carrier by bonding wires, after which the contact areas and contact connecting areas and bonding wires or else the entire electronic component is potted in a housing.

The first external contacts of the first semiconductor chip and the second external contacts of the intermediate carrier are, preferably, formed respectively as first and second contact bumps, which permits flip-chip mounting of the electronic component on a printed circuit board or the like.

The advantage of such a process for the production of the electronic component lies in the very short processing cycles and in the high precision in the production of extremely compact electronic components.

Stacking the semiconductor chips saves mounting area as compared with so-called single-chip solutions. In addition, so-called multi-chip modules are normally substantially more voluminous than an electronic component according to the invention. In addition, stacking the semiconductor chips in a housing saves mounting height as compared with multi-chip modules. The modularity of the housing makes it easier to perform individual functional tests of the functional groups used and, as a result, can significantly increase the yield as compared with integrated modules. As a result of the simple construction of the intermediate carrier, the latter can be kept very cost-effective.

The construction can be standardized and expanded and permits the use of geometrically different circuits with a low number of terminals but with the same functionality without changing the connection construction of the overall configuration. This means that the external contacts of the electronic component according to the invention can easily be matched to already existing connection configurations. In addition, changing the intermediate carrier can easily be implemented in a simple and cost-effective way. Moreover, a plurality of circuits with a low number of terminals (e.g., memory chips) can be combined into one electronic component without a fundamental change of the connection configuration.

The two different semiconductor chips are preferably not connected to each other electrically but only mechanically. Electrical connections are made through the target system, that is to say, normally, the printed circuit board, on which the electronic component is mounted.

In a first embodiment of the invention, the chip with a low number of terminals (memory module) is mounted on the intermediate carrier by die-bonding, as it is referred to in the art. Contact is made through bonding wires. The intermediate carrier can, for example, be a wiring carrier made of conventional material, such as epoxy resin, rigid glass fabric, ceramic, or, for example, a back-etched lead frame. In the case of multi-layer systems, the intermediate carrier is composed of two layers, one layer being disposed flat under the circuit with few terminals, and the second layer forming erect supporting feet. The flat layer accepts wire bonding on its surface to make contact with the chip with a low number of terminals. Such a structure is provided with a protective layer or covering, which can, for example, be composed of a varnish layer or a cast plastic layer. The protective covering can, for example, also be produced by transfer molding. The layer having the supporting feet can be populated with solder beads.

Such a composite is built up, separated from the blank, and tested. The matrix-contacted circuit (processor module) is passivated on its active side and populated with solder beads and tested. To finish the structure, the two components are connected to each other through an adhesive layer, which must be heat-conducting in order to support the reflow process of the overall construction. Furthermore, the adhesive must either be brittle in the sense of an intended fracture point under thermo-mechanical stresses or permanently elastic. Exact joining is required, the tolerances being determined by the positional tolerances of the solder beads.

The chip with few terminals can be connected to the intermediate carrier either through wire-bonding connections or connected thereto as a flip-chip component.

The circuit with few terminals can also be mounted on a frame, which is constructed in one layer. The passivation of the connections is carried out by a polymer covering (globe-top, molding). The mounting of the matrix-contacted circuit is carried out by adhesive bonding directly to the circuit having few terminals.

The matrix-contacted circuit considered is, for example, a GSM baseband controller that is combined with flash memories in one component.

Other features that are considered as characteristic for the invention are set forth in the appended claims.

Although the invention is illustrated and described herein as embodied in an electronic component with at least two semiconductor chips, and process for its production, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a diagrammatic plan view of a first semiconductor chip according to the invention;

FIG. 2 is diagrammatic plan view of a first variant of a second semiconductor chip according to the invention;

FIG. 3 is a diagrammatic plan view of a second variant of the second semiconductor chip of FIG. 2;

FIG. 4 is a diagrammatic plan view of a first variant of an electronic component according to the invention;

FIG. 5 is a diagrammatic cross-sectional view of the electronic component of FIG. 4;

FIG. 6 is a diagrammatic plan view of a second variant of an electronic component according to the invention;

FIG. 7 is a diagrammatic cross-sectional view of the electronic component of FIG. 6;

FIG. 8 is a diagrammatic plan view a third variant of an electronic component according to the invention;

FIG. 9 is a diagrammatic cross-sectional view of the electronic component of FIG. 8; and

FIG. 10 is a diagrammatic plan view a fourth variant of an electronic component according to the invention.

### DESCRIPTION OF THE PREFERRED EMBODIMENTS

By using FIGS. 1 to 10, various variants of an electronic component according to the invention and processes for the production of the components will be described in the following text. Parts or subassemblies that are fundamentally the same are provided with the same designations. They are, therefore, to some extent not explained repeatedly.

Referring now to the figures of the drawings in detail and first, particularly to FIG. 1 thereof, there is shown a schematic plan view of a first semiconductor chip 4, which is provided with a large number of first contact areas 44 on a first active chip surface 41. In the exemplary embodiment shown, the first semiconductor chip 4 has a square contour. The first contact areas 44 are distributed on the first active chip surface 41 in the form of a regular matrix and are provided to be populated with solder beads or the like so that the first semiconductor chip 4 can be mounted in the flip-chip technique.

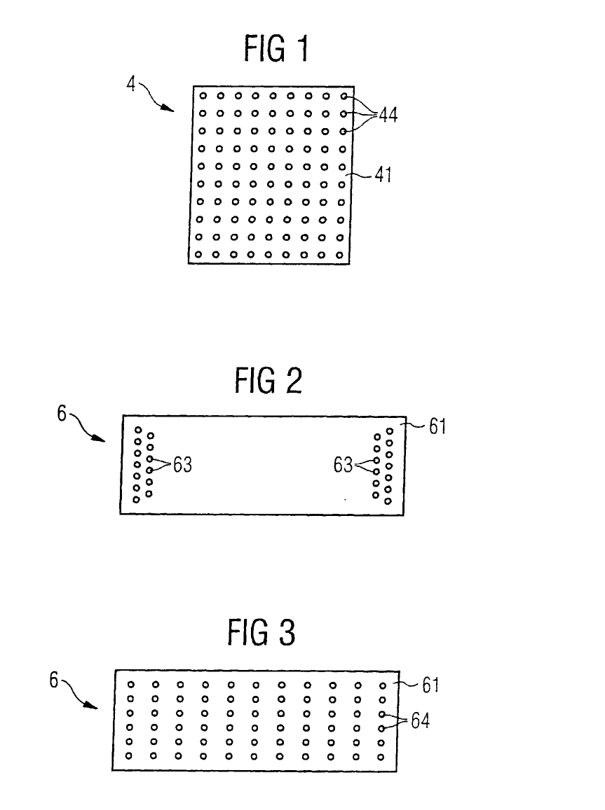

FIG. 2 shows a schematic plan view of a second semiconductor chip 6, which is provided with a large number of second contact areas 63 on a second active chip surface 61. In the exemplary embodiment shown, the second semiconductor chip 6 has a rectangular contour. The second contact areas 63 are respectively located at the edge on the two narrow sides of the rectangle. In the exemplary embodiment shown, the second contact areas 63 are respectively configured in two rows and are provided for connection to bonding wires.

FIG. 3 shows a further schematic plan view of a variant of the second semiconductor chip 6, which likewise has a rectangular outline and is provided with a large number of third contact areas 64 on its second active chip surface. The third contact areas 64 are distributed on the entire second active chip surface 61 in the form of a matrix. This variant of the second semiconductor chip 6 is provided for flip-chip mounting, the third contact areas 64 in each case having to be provided with external contacts, for example, in the form of solder beads or the like.

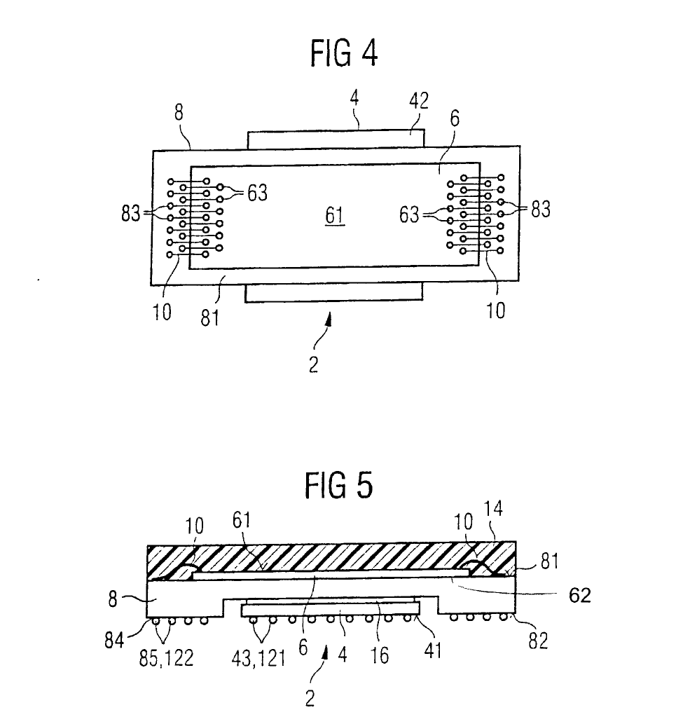

FIG. 4 shows a schematic plan view of an electronic component 2 according to the invention. This includes an intermediate carrier 8, a second semiconductor chip 6 mounted thereon, and a first semiconductor chip 4 mounted underneath. An underside of the intermediate carrier 8 is connected to a first passive rear side 42 of the first semiconductor chip 4. The second semiconductor chip 6 is placed on an upper side 81 of the intermediate carrier 8, its second passive rear side 62 facing the upper side 81. Furthermore, a large number of contact connecting areas 83 are provided on the upper side 81 of the intermediate carrier, respectively corresponding with the second contact areas 63 at the edge of the second semiconductor chip 6 and connected to the latter through bonding wires 10.

FIG. 5 shows a schematic cross-section of the electronic component 2 according to FIG. 4, a covering in the form of a housing 14 additionally being provided here on the upper side 81 of the intermediate carrier, covering the upper side 81 of the intermediate carrier 8, the second semiconductor chip 6, and the bonding wires 10. The intermediate carrier 8 has a stepped contour so that the first semiconductor chip 4 connected to the underside 82 rests with its first active chip surface 41 on one plane with the underside 82 of the intermediate carrier.

The semiconductor chip 4 is connected to the underside 82 of the intermediate carrier 8 by its first passive rear side 42, through a first adherent layer 16. Provided on the underside 82 are external contact areas 84, onto which the second external contacts 85 in the form of second contact bumps 122 are placed. The first contact areas 44 of the first semiconductor chip 4 are provided with first external contact areas 43 in the form of first contact bumps 121. The second contact areas 63 of the second semiconductor chip 6 have an electrical connection to the external contact areas 84 through the bonding wires 10 and rerouting device provided in the intermediate carrier 8.

The electronic component 2 is, therefore, provided for flip-chip mounting and can, for example, be mounted on a printed circuit board. By using FIGS. 4 and 5, which show a first variant of the electronic component 2 according to the invention, it can be seen that even in the case of semiconductor chips with a different external contour, an implementation of very compact and flat electronic components is possible. Although the first semiconductor chip 4 projects beyond the second semiconductor chip 6 at its long sides, and the second semiconductor chip 6 projects beyond the first semiconductor chip 4 at its narrow sides, these chips can, nevertheless, be combined in a very compact electronic component 2.

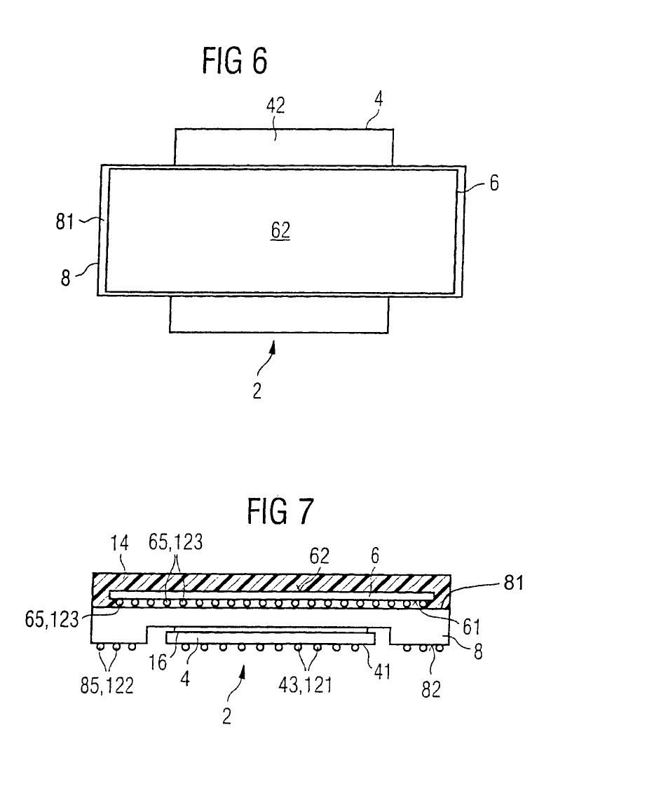

FIG. 6 shows a schematic plan view of a second variant of the electronic component 2 according to the invention. The external contours of the first semiconductor chip 4 and of the second semiconductor chip 6 in this case correspond to the dimensions of the first variant (FIGS. 4 and 5). The intermediate carrier 8 is smaller here, however, and its external contours project only minimally beyond the second semiconductor chip 6. In addition, in the second variant, the second active chip surface 61 faces the upper side 81 of the intermediate carrier 8 so that the second passive rear side 62 of the second semiconductor chip 6 points upward.

FIG. 7 shows the second variant of the electronic component 2 according to the invention and according to FIG. 6 in a further schematic cross section. In this case, it can be seen that the second semiconductor chip 6 has a large number of third external contacts 65 in the form of second contact bumps 122, which are electrically connected to contact connecting areas 83 (not illustrated here; see, i.e., FIG. 1), on the upper side 81 of the intermediate carrier 8. The second semiconductor chip 6 is, therefore, mounted on the intermediate carrier 8 in the flip-chip technique.

Connecting the intermediate carrier 8 to the first semiconductor chip 4 corresponds to the greatest extent to the first variant according to FIG. 5. The second semiconductor chip 6 and its electrical connections to the intermediate carrier 8 are enclosed by the housing 14.

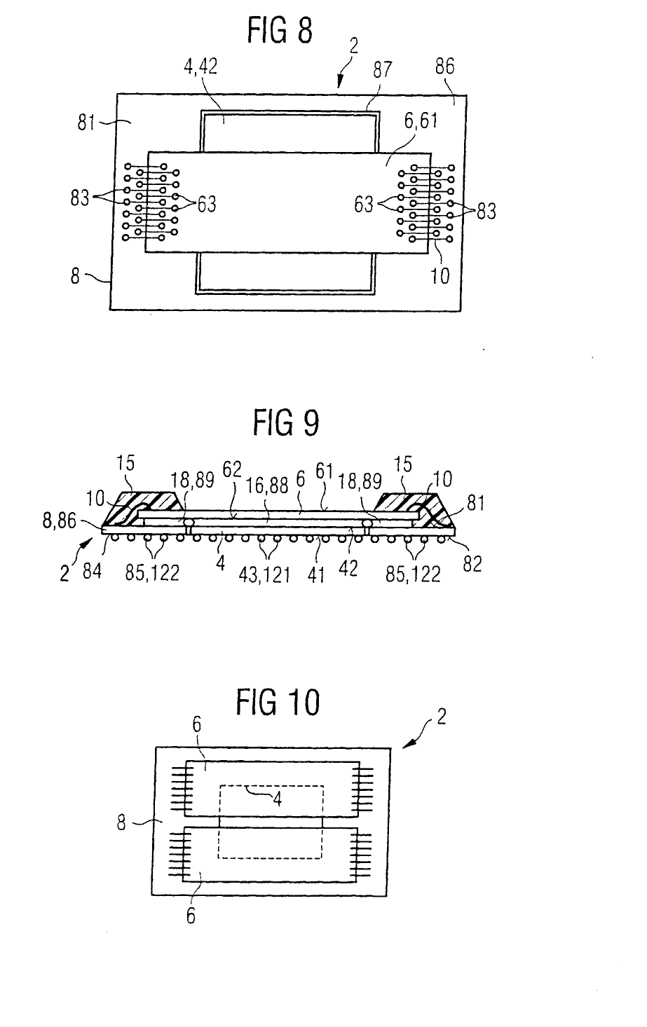

FIG. 8 shows a third variant of the electronic component 2 according to the invention in a schematic plan view. The second semiconductor chip 6 with its second contact areas 63 on its second active chip surface 61 corresponds to the configuration according to FIG. 2. The intermediate carrier 8 includes a frame 86 and a cutout 87 disposed centrally therein, into which the first semiconductor chip 4 fits with slight play. Again provided on the upper side 81 of the frame 86 are contact connecting areas 83, which are connected through bonding wires 10 to the second contact areas 63 on the second active chip surface 61 of the second semiconductor chip 6.

FIG. 9 shows the third variant of the electronic component 2 according to the invention and according to FIG. 8 in a cross sectional illustration. In this case, it can be seen that the first semiconductor chip 4 and the second semiconductor chip 6 are connected directly to each other through a first supporting area 88 and the first adherent layer 16. At its narrow edges, the second semiconductor chip 6 is respectively provided with second supporting areas 89, which are respectively connected to the upper side 81 of the frame 86 through a second adherent layer 18.

The structure of the third variant of the electronic component 2 can, therefore, be configured to be still more substantially compact than that of the first and second variants. The bonding connections 10, the second contact areas 63, and the contact connecting areas 83 are in each case provided with a covering 15 that, for example, can be composed of a varnish layer or a plastic layer.

The first and the second adherent layers 16, 18 are, for example, configured as an adhesive layer or as a solder layer. The intermediate carrier 8 can be composed of ceramic, or epoxy material or, for example, of polyimide. The electrical connections between the contact connecting areas 83 on the upper side 81 of the intermediate carrier 8 and the external contact areas 84 on its underside 82 can, if appropriate, also be led in a three-dimensional structure. As a result, the intermediate carrier 8 becomes a rerouting board.

FIG. 10 shows a schematic plan view of a fourth variant of the electronic component 2 according to the invention, in which two second semiconductor chips 6 are placed on one intermediate carrier 8. The first semiconductor chip 4 is illustrated by partially interrupted lines. In addition to the embodiment shown in FIG. 10, virtually any desired combinations each having respectively different numbers of first and second semiconductor chips 4, 6 are conceivable.

Using FIGS. 1, 2, 4, and 5, a process for the production of the first variant of the electronic component according to the invention will be presented below. First of all, a first semiconductor chip 4 with first contact areas 44 on a first active chip surface 41 is provided (cf. FIG. 1). A second semiconductor chip 6 with second contact areas 63 on a second active chip surface 61 is provided (cf. FIG. 2).

Furthermore, an intermediate carrier 8 is provided that has a stepped cross-section and is provided with external contact areas 84 on its underside 82. The second semiconductor chip 6 is fixed with its second passive rear side 62 on the upper side 81 of the intermediate carrier 8, for example, by a conductive adhesive or solder layer. Electrical connections are then produced between second contact areas 63 of the second semiconductor chip 6 and contact connecting areas 83 on the upper side 81 of the intermediate carrier 8, preferably, by bonding wires 10.

The first semiconductor chip 4 is fixed with its first passive rear side 42 on the underside 82 of the intermediate carrier 8 so that its first active chip surface 41 with the first external contacts 43 located on it points downward and rests with second external contacts 85 on the underside 82 of the intermediate carrier 8 on one plane. Finally, the upper side 81 of the intermediate carrier 8, the bonding wires 10, and the second semiconductor chip 6 are encapsulated by a housing 14. This can be carried out, for example, by a transfer molding process.

In a process for the production of a second variant of the electronic component according to the invention, the second semiconductor chip 6 is provided with third external contacts 65 in the form of third contact bumps 123 (cf. FIG. 3). The second semiconductor chip 6 is placed on the upper side 81 of the intermediate carrier 8 in the flip-chip technique, with its third contact bumps 123 on corresponding contact connecting areas 83 (cf. FIGS. 6, 7). The other process steps correspond to those from the process previously described.

In a further process for the production of a third variant of the electronic component 2 (cf. FIGS. 8 and 9), following the provision of the first and second semiconductor chips 4, 6 and the provision of a flat intermediate carrier 8 including a frame 86 and a central cutout 87, the first passive rear side 42 of the first semiconductor chip 4 is joined to the second passive rear side 62 of the second semiconductor chip 6. The second semiconductor chip 6 is then placed on supporting areas 89 at the edges on the upper side 81 of the frame 86 of the intermediate carrier 8. The third contact areas 64 of the second semiconductor chip 6 are connected to contact connecting areas 83 of the intermediate carrier 8 by bonding wires 10. Then, either the entire surface of the electronic component 2 or, optionally, also only the contact areas 64 and contact connecting areas 83 together with the bonding wires are potted (cf. FIG. 9).

The production of an electronic component 2 with more than two semiconductor chips, as shown by way of example in FIG. 10, is carried out in principle in the same way as that previously described. In principle, it is also possible for a plurality of first semiconductor chips 4 to be combined with a plurality of second semiconductor chips 6 and a common intermediate carrier 8 to form one electronic component.

We claim:

1. An electronic component, comprising:
at least one first semiconductor chip having:
a first active chip surface with first external contacts disposed in a given plane; and
a first passive rear side;
at least one second semiconductor chip having:
a second active chip surface; and
a second passive rear side;
said first passive rear side facing one of said second active chip surface and said second passive rear side; and
an intermediate carrier having:
a carrier upper side holding said at least one second semiconductor chip; and
an underside having second external contacts located on said given plane.

2. The electronic component according to claim 1, wherein:
said first external contacts are first contact bumps; and
said second external contacts are second contact bumps.

3. The electronic component according to claim 1, wherein said at least one first semiconductor chip rests with said first passive rear side on said underside of said intermediate carrier and is permanently connected thereto.

4. The electronic component according to claim 1, wherein said first passive rear side of said at least one first semiconductor chip is permanently connected to said underside of said intermediate carrier.

5. The electronic component according to claim 1, wherein said at least one first semiconductor chip rests with said first passive rear side on said second passive rear side of said second semiconductor chip and is permanently connected thereto.

6. The electronic component according to claim 1, wherein said first passive rear side of said at least one first semiconductor chip is permanently connected to said second passive rear side of said second semiconductor chip.

7. The electronic component according to claim 1, wherein said intermediate carrier has a stepped cross-section.

8. The electronic component according to claim 1, wherein said intermediate carrier has a planar and frame-shaped contour with a cutout.

9. The electronic component according to claim 1, wherein said intermediate carrier has:
a contour with a cutout; and
said contour is planar and frame-shaped.

10. The electronic component according to claim 8, wherein said at least one first semiconductor chip is disposed in said cutout and at a distance from said frame.

11. The electronic component according to claim 1, wherein:
said second passive rear side of said at least one second semiconductor chip faces said at least one first semiconductor chip; and
bonding wires electrically conductively connect said at least one second semiconductor chip to said carrier upper side.

12. The electronic component according to claim 1, wherein:
said second active chip surface of said at least one second semiconductor chip faces said at least one first semiconductor chip;
said carrier upper side has contact connecting areas; and
third external contacts electrically conductively connect said at least one second semiconductor chip to said contact connecting areas on said carrier upper side in a flip-chip technique.

13. The electronic component according to claim 1, wherein said intermediate carrier is a rerouting board.

14. The electronic component according to claim 1, wherein said at least one first semiconductor chip is square and is a processor module.

15. The electronic component according to claim 1, wherein said at least one second semiconductor chip is rectangular and is a memory module.

16. The electronic component according to claim 1, including a single housing accommodating said at least one first semiconductor chip and said at least one second semiconductor chip.

17. A method of producing an electronic component, which comprises:
providing:
at least one first semiconductor chip having:
a first active chip surface having first contact areas and first external contacts, the first external contacts disposed in a given plane; and
a first passive rear side;
at least one second semiconductor chip having:
a second active chip surface having second and third contact areas;
a second passive rear side; and
one of the second active chip surface and the second passive rear side facing the first passive rear side; and
an intermediate carrier having:
a stepped cross-section;
an upper side having contact connecting areas; and
an underside having second external contacts disposed in the given plane;
fixing the at least one second semiconductor chip to the upper side of the intermediate carrier;
producing electrical connections between the second and third contact areas and the contact connecting areas;
fixing the first passive rear side of the at least one first semiconductor chip to the underside of the intermediate carrier; and
potting the at least one first semiconductor chip, the at least one second semiconductor chip, and the intermediate carrier in a housing.

18. The method according to claim 17, which further comprises producing electrical connections between the second contact areas and the contact connecting areas with bonding wires.

19. The method according to claim 17, which further comprises producing electrical connections between the third contact areas and the contact connecting areas with third external contacts.

20. The method according to claim 19, wherein the third external contacts are contact bumps, and which further comprises connecting the at least one second semiconductor chip to the intermediate carrier by a flip-chip technique.

21. The method according to claim 19, wherein the third external contacts are contact bumps, and which further comprises flip-chip connecting the at least one second semiconductor chip to the intermediate carrier.

22. The electronic component according to claim 17, wherein:
the first external contacts are first contact bumps; and
the second external contacts are second contact bumps.

23. A method of producing an electronic component, which comprises:
providing:
at least one first semiconductor chip having:
a first active chip surface having first contact areas and first external contacts, the first external contacts disposed in a given plane; and
a first passive rear side;
at least one second semiconductor chip having:
a second active chip surface having second contact areas; and
a second passive rear side facing the first passive rear side; and
a flat intermediate carrier having:
a frame defining a central cutout, the frame having:
an upper side having an edge and contact connecting areas;
supporting areas on the edge of the upper side of the frame; and
an underside having second external contacts disposed in the given plane;
holding at least one of the at least one first semiconductor chip and the at least one second semiconductor chip on the upper side of the intermediate carrier;
joining the first passive rear side to the second passive rear side;
fixing the at least one second semiconductor chip to the supporting areas;
connecting the second contact areas to the contact connecting areas with bonding wires; and
potting the at least one first semiconductor chip, the at least one second semiconductor chip, and the intermediate carrier in a housing.

24. The electronic component according to claim 23, wherein:
the first external contacts are first contact bumps; and
the second external contacts are second contact bumps.

25. A method of producing an electronic component according to claim 1, which comprises:
providing:
at least one first semiconductor chip having:
a first active chip surface having first contact areas and first external contacts, the first external contacts disposed in a given plane; and
a first passive rear side;
at least one second semiconductor chip having:
a second active chip surface having second and third contact areas;
a second passive rear side; and
one of the second active chip surface and the second passive rear side facing the first passive rear side; and
an intermediate carrier having:
a stepped cross-section;
an upper side having contact connecting areas; and
an underside having second external contacts disposed in the given plane;
fixing the at least one second semiconductor chip to the upper side of the intermediate carrier;
producing electrical connections between the second and third contact areas and the contact connecting areas;
fixing the first passive rear side of the at least one first semiconductor chip to the underside of the intermediate carrier; and
potting the at least one first semiconductor chip, the at least one second semiconductor chip, and the intermediate carrier in a housing.

26. A method of producing an electronic component according to claim 1, which comprises:
providing:
at least one first semiconductor chip having:
a first active chip surface having first contact areas and first external contacts, the first external contacts disposed in a given plane; and
a first passive rear side;
at least one second semiconductor chip having:
a second active chip surface having second contact areas; and
a second passive rear side facing the first passive rear side; and
a flat intermediate carrier having:
a frame defining a central cutout, the frame having:
an upper side having an edge and contact connecting areas;
supporting areas on the edge of the upper side of the frame; and
an underside having second external contacts disposed in the given plane;
holding at least one of the at least one first semiconductor chip and the at least one second semiconductor chip on the upper side of the intermediate carrier;
joining the first passive rear side to the second passive rear side;
fixing the at least one second semiconductor chip to the supporting areas;
connecting the second contact areas to the contact connecting areas with bonding wires; and
potting the at least one first semiconductor chip, the at least one second semiconductor chip, and the intermediate carrier in a housing.
